(19) United States
(12) Patent Application Publication
(10) Pub. No.: US 2025/0234501 A1
(43) Pub. Date: Jul. 17, 2025

(54) Static Random Access Memory

(71) Applicant: UNITED MICROELECTRONICS CORP., Hsin-Chu City (TW)

(72) Inventors: Yen-Hsueh Huang, Taipei City (TW); Tsan-Tang Chen, Miaoli County (TW)

(73) Assignee: UNITED MICROELECTRONICS CORP., Hsin-Chu City (TW)

(21) Appl. No.: 18/581,327

(22) Filed: Feb. 19, 2024

(30) Foreign Application Priority Data
Jan. 16, 2024 (TW) 113101643

(51) Int. Cl. H10B 10/00; G11C 11/41

(52) U.S. Cl. CPC H10B 10/00; G11C 11/41

(57) ABSTRACT

A static random access memory (SRAM) includes a precharge circuit, two bit lines, and a plurality of memory cells. The precharge circuit has three transistors and two equivalent diodes. Control ends of the three transistors receive a precharge signal. First ends of two of the transistors are coupled to a reference voltage source, and second ends of the two transistors are coupled to the anodes of the two equivalent diodes. The remaining transistor of the three transistors is coupled between the two bit lines. The cathodes of the two equivalent diodes are coupled to the two bit lines to output a first precharge voltage and a second precharge voltage. Each memory cell is coupled between the two bit lines.

### BACKGROUND OF THE INVENTION

### 1. Field of the Invention

The present invention is related to a static random access memory (SRAM), and more particularly to an SRAM that maintains high stability under high-temperature conditions.

### 2. Description of the Prior Art

Static random-access memory (SRAM) is a type of random-access memory that retains its data as long as it is powered. Compared to dynamic random-access memory (DRAM), SRAM has a faster access speed and lower power consumption. This makes it ideal for high-speed applications such as being a cache memory of a central processing unit (CPU). However, SRAM stability is critical in high-temperature environments because it may lose data under such conditions.

### SUMMARY OF THE INVENTION

An embodiment of the present invention provides a static random-access memory (SRAM). The SRAM comprises a first precharge circuit, a first bit line, a second bit line, and a plurality of SRAM cells. The first precharge circuit comprises a first transistor, a second transistor, a first equivalent diode, a second equivalent diode, and a third transistor. The first transistor comprises a first end coupled to a first reference voltage source, a second end, and a control end configured to receive a first precharge signal. The second transistor comprises a first end coupled to the first reference voltage source, a second end, and a control end configured to receive the first precharge signal. The first equivalent diode comprises an anode coupled to the second end of the first transistor, and a cathode configured to output a first precharge voltage. The second equivalent diode comprises an anode coupled to the second end of the second transistor, and a cathode configured to output a second precharge voltage. The third transistor comprises a first end coupled to the cathode of the first equivalent diode, a second end coupled to the cathode of the second equivalent diode, and a control end configured to receive the first precharge signal. The first bit line is coupled to the cathode of the first equivalent diode and configured to receive the first precharge voltage. The second bit line is coupled to the cathode of the second equivalent diode and configured to receive the second precharge voltage. Each of the SRAM cells is coupled between the first bit line and the second bit line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a static random-access memory (SRAM) according to one embodiment of the present invention.

FIG. 2 is a circuit diagram of an SRAM according to another embodiment of the present invention.

FIG. 3 is a circuit diagram of an SRAM according to another embodiment of the present invention.

FIG. 4 is a circuit diagram of an SRAM according to another embodiment of the present invention.

FIG. 5 is a timing diagram of the relevant voltages when the static random-access memories shown in FIGS. 1 and 4 perform read operations.

FIG. 6 is a diagram shown relationship between the operating voltage and the static noise margin (SNM) of the static random-access memories shown in FIGS. 1 and 4.

### DETAILED DESCRIPTION

An embodiment of the present invention provides a static random access memory (SRAM), which may comprise a memory cell array, a plurality of bit lines, and a plurality of word lines. The SRAM can be a single port SRAM or a dual port SRAM. The memory cell array may comprise a plurality of static random access memory cells (hereinafter referred to as “SRAM cells”) arranged in a plurality of rows and columns. For a single port SRAM, each column of SRAM cells shares a set of two bit lines, each row of SRAM cells shares a corresponding word line, and each row of SRAM cells shares a precharge circuit for precharging the two bit lines. For a dual port SRAM, each column of SRAM cells shares two sets of four bit lines, each row of SRAM cells shares two corresponding word lines, and each row of SRAM cells shares two precharge circuits for precharging the four bit lines.

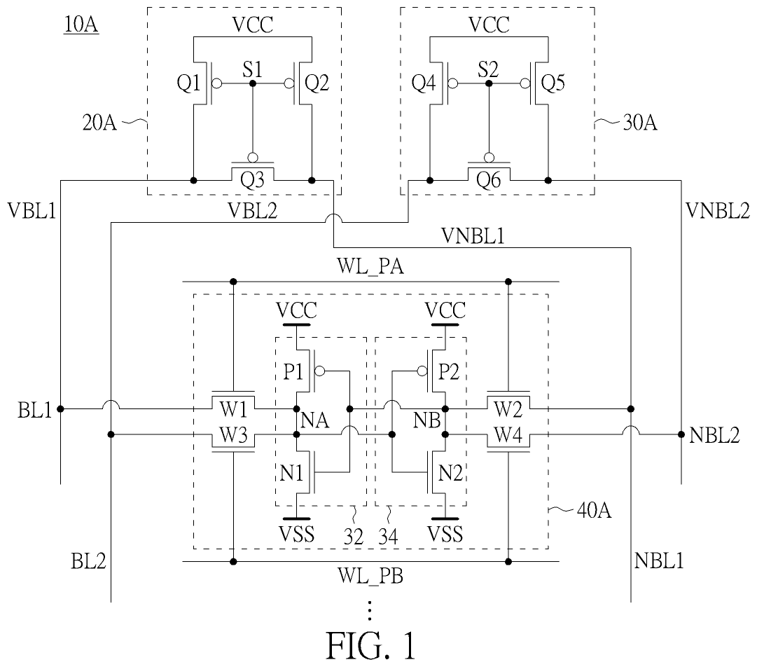

Please refer to FIG. 1, which is a circuit diagram of a static random access memory (SRAM) 10A according to an embodiment of the present invention. The SRAM 10A is a dual port SRAM and comprises two sets of four bit lines BL1, BL2, NBL1, and NBL2. The bit lines BL1 and NBL1 are in the same set, and the bit lines BL2 and NBL2 are in the same set. The SRAM 10A also comprises two precharge circuits 20A and 30A. The precharge circuit 20A outputs precharge voltages VBL1 and VNBL1 to the bit lines BL1 and NBL1 based on a precharge signal S1, and the precharge circuit 30A outputs precharge voltages VBL2 and VNBL2 to the bit lines BL2 and NBL2 based on a precharge signal S2. The SRAM 10A further comprises a plurality of SRAM cells 40A and a plurality of word lines (such as: WL PA and WL PB). Each SRAM cell 40A adopts an 8T structure, that is, each SRAM cell 40A comprises eight transistors, and the eight transistors are four switches and four transistors. The four switches are switches W1, W2, W3, and W4 composed of N-type transistors, and the four transistors are two N-type transistors N1, N2 and two P-type transistors P1, P2. The P-type transistor P1 and the N-type transistor N1 form an inverter 32, the P-type transistor P2 and the N-type transistor N2 form another inverter 34, and the inverters 32 and 34 form a latch circuit. The input end of inverter 32 serves as storage node NA, and the input end of inverter 34 serves as another storage node NB. When the SRAM 10A stores “1”, the storage node NA is latched at a high voltage, and the storage node NB is latched at a low voltage. When the SRAM 10A stores “0”, the storage node NA is latched at a low voltage, and the storage node NB is latched at a high voltage.

The SRAM cell 40A is a dual-port SRAM cell, that is, each SRAM cell 40A has two ports (hereinafter referred to as port A and port B). The bit line BL1, the bit line NBL1, the word line WL PA, the switch W1, and the switch W2 belong to the port A; and the bit line BL2, the bit line NBL2, the word line WL PB, the switch W3, and the switch W4 belong to the port B. In the port A, the word line WL PA controls the operations of the switches W1 and W2, and data can be stored in the SRAM cell 40A or read from the SRAM cell 40A through the bit line BL1 and the bit line NBL1. Similarly, in the port B, the word line WL_PB controls the operations of the switches W3 and W4, and the data can be stored in the SRAM cell 40A or read from the SRAM cell 40A through the bit line BL2 and the bit line NBL2. The port A and the port B can access the SRAM cell 40A at the same time, thereby improving the performance of the SRAM 10A. Further, the SRAM 10A can access the SRAM cell 40A through only one of the ports A and B, or can access the SRAM cell 40A through both the ports A and B at the same time. When a read operation of the SRAM cell 40A is performed through one of the ports A and B, and a write operation of SRAM cell 40A is performed through the other port of the ports A and B, the data read by the read operation will be the data stored in the SRAM cell 40A before the write operation is performed.

The precharge circuit 20A comprises a transistor Q1, a transistor Q2, and a transistor Q3, and the precharge circuit 30A comprises a transistor Q4, a transistor Q5, and a transistor Q6. The transistors Q1 to Q6 can be P-type transistors. A first end of the transistor Q1 is coupled to a reference voltage source VCC, a second end of the transistor Q1 is coupled to the bit line BL1, and the gate of the transistor Q1 being a control end receives the precharge signal S1. A first end of the transistor Q2 is coupled to the reference voltage source VCC, a second end of the transistor Q2 is coupled to the bit line NBL1, and the gate of the transistor Q2 being a control end receives the precharge signal S1. A first end of the transistor Q3 is coupled to the bit line BL1, a second end of the transistor Q3 is coupled to the bit line NBL1, and the gate of the transistor Q3 being a control end receives the precharge signal S1. When the precharge signal S1 is at a low voltage, the transistors Q1, Q2, and Q3 are all turned on, causing the bit lines BL1 and NBL1 to be precharged, and making the precharge voltages VBL1 and VNBL1 equal to the voltage of the reference voltage source VCC. When the precharge signal S1 is at a high voltage, the transistors Q1, Q2, and Q3 are all turned off. A first end of the transistor Q4 is coupled to the reference voltage source VCC, a second end of the transistor Q4 is coupled to the bit line BL2, and the gate of the transistor Q4 being a control end receives the precharge signal S2. A first end of the transistor Q5 is coupled to the reference voltage source VCC, a second end of the transistor Q5 is coupled to bit line NBL2, and the gate of the transistor Q5 being a control end receives the precharge signal S2. A first end of the transistor Q6 is coupled to the bit line BL2, a second end of the transistor Q6 is coupled to the bit line NBL2, and the gate of the transistor Q6 being a control end receives the precharge signal S2. When the precharge signal S2 is at a low voltage, the transistors Q4, Q5, and Q6 are all turned on, causing the bit lines BL2 and NBL2 to be precharged, and making the precharge voltages VBL2 and VNBL2 equal to the voltage of the reference voltage source VCC. When the precharge signal S2 is at a high voltage, the transistors Q4, 05, and Q6 are all turned off.

A first end of the switch W1 is coupled to the bit line BL1, a second end of the switch W1 is coupled to the input end of the inverter 32 (i.e., the storage node NA) and the output end of the inverter 34 (i.e., the gates of the P-type transistor P2 and the N-type transistor N2), and the gate of the switch W1 being a control end is coupled to the word line WL PA. A first end of the switch W2 is coupled to the bit line NBL1, a second end of the switch W2 is coupled to the output end of the inverter 32 (i.e., the gates of the P-type transistor P1 and the N-type transistor N1) and the input end of the inverter 34 (i.e., the storage node NB), and the gate of the switch W2 being a control end is coupled to the word line WL PA. A first end of the switch W3 is coupled to the bit line BL2, a second end of the switch W3 is coupled to the input end of the inverter 32 and the output end of the inverter 34, and the gate of the switch W3 being a control end is coupled to the word line WL_PB. A first end of the switch W4 is coupled to the bit line NBL2, a second end of the switch W4 is coupled to the output end of inverter 32 and the input end of the inverter 34, and the gate of the switch W4 being a control end is coupled to the word line WL_PB.

In the inverter 32, a first end of the P-type transistor P1 is coupled to the reference voltage source VCC, a second end of the P-type transistor P1 is coupled to the second end of the switch W1 and the second end of the switch W3, and the gate of the P-type transistor P1 being a control end is coupled to the second end of the switch W2 and the second end of the switch W4. In the inverter 32, a first end of the N-type transistor N1 is coupled to the second end of the P-type transistor P1, a second end of the N-type transistor N1 is coupled to the reference voltage source VSS, and the gate of the N-type transistor N1 being a control end is coupled to the control end of the P-type transistor P1. The voltage of the reference voltage source VCC is higher than the voltage of reference voltage source VSS, the voltage of the reference voltage source VCC can be a positive voltage, and the voltage of reference voltage source VSS can be a ground voltage. In the inverter 34, a first end of the P-type transistor P2 is coupled to the reference voltage source VCC, a second end of the P-type transistor P2 is coupled to the control end of the P-type transistor P1, and the gate of the P-type transistor P2 being a control end is coupled to the second end of the switch W1 and the second end of the switch W3. In the inverter 34, a first end of the N-type transistor N2 is coupled to the control end of the P-type transistor P1, a second end of the N-type transistor N2 is coupled to the reference voltage source VSS, and the gate of the N-type transistor N2 being a control end is coupled to the second end of the P-type transistor P1.

The SRAM cell 40A usually operates in three states: “standby”, “read”, and “write”. In the “standby” state, the SRAM cell 40A is idle and waits for the issuance of write or read instructions. In the “standby” state, the word lines WL PA and WL_PB are not set, and the turned-off switches W1, W2, W3, and W4 electrically disconnect the two inverters 32 and 34 from the bit lines BL1, BL2, NBL1, and NBL2. The two inverters 32 and 34 continuously store data in a latch structure, so the data stored in the SRAM cell 40A will not change.

In the “read” state, the data stored in the SRAM cell 40A will be read out. Since the SRAM cell 40A is a dual-port SRAM cell, the stored data can be read simultaneously through the aforementioned port A and port B, or it can be read through one of the port A and the port B. For ease of explanation, the following explanation will use simultaneous reading through the port A and the port B. Suppose that before the “read” operation, the data stored in SRAM 10A is “1” (that is, the storage node NA is latched at a high voltage, and the storage node NB is latched at a low voltage). During the “read” operation, the precharge signals S1 and S2 are set to a low voltage, causing the transistors Q1 to Q6 to turn on, the precharge circuit 20A will precharge the bit lines BL1 and NBL1, and the precharge circuit 30A will precharge the bit lines BL2 and NBL2. When the precharge signals S1 and S2 are set to a low voltage, the word lines WL_PA and WL_PB are at a low voltage, turning off the switches W1, W2, W3, and W4. After the precharge circuits 20A and 30A complete the precharge of the bit lines BL1, BL2, NBL1, and NBL2, the bit lines BL1, BL2, NBL1, and NBL2 will be in a floating state. Then, the word lines WL_PA and WL_PB are set to a high voltage to turn on the switches W1, W2, W3, and W4. After the switches W1, W2, W3, and W4 are turned on, the voltages of the bit lines BL1 and BL2 will remain at a high voltage, and the voltages of the NBL1 and NBL2 will be pulled down from a high voltage to a low voltage. Therefore, the data stored in the SRAM cell 40A can be determined to be “1” by the voltages of the bit lines BL1, BL2, NBL1, and NBL2. Similarly, if the data stored in the SRAM 10A is “0”, when a read operation of the SRAM cell 40A is performed, the voltages of the bit lines BL1 and BL2 will be pulled down from a high voltage to a low voltage, and the voltages of the bit lines NBL1 and NBL2 will remain at a high voltage.

In the “write” state, the data stored in the SRAM cell 40A will be updated. For ease of explanation, the following explanation will use simultaneous writing through the port A and the port B. Suppose that before the “write” operation, the data stored in the SRAM 10A is “1” (that is, the storage node NA is latched at a high voltage, and the storage node NB is latched at a low voltage). If the data to be written is “0”, the bit lines BL1 and BL2 will be set to the low voltage of reference voltage source VSS, and the other two bit lines NBL1 and NBL2 will be set to the high voltage of the reference voltage source VCC. Then, the word lines WL_PA and WL_PB are set to a high voltage to turn on the switches W1, W2, W3, and W4. After the switches W1, W2, W3, and W4 are turned on, the storage node NA switches from a high voltage to a low voltage, and the storage node NB switches from a low voltage to a high voltage. Then, the word lines WL_PA and WL_PB are set to a low voltage to turn off the switches W1, W2, W3, and W4. In this way, the data of “0” can be written into the SRAM cell 40A. Similarly, when data of “1” is to be written into the SRAM cell 40A, the bit lines BL1 and BL2 will be set to the high voltage of the reference voltage source VCC, and the other two bit lines NBL1 and NBL2 will be set to the low voltage of the reference voltage source VSS.

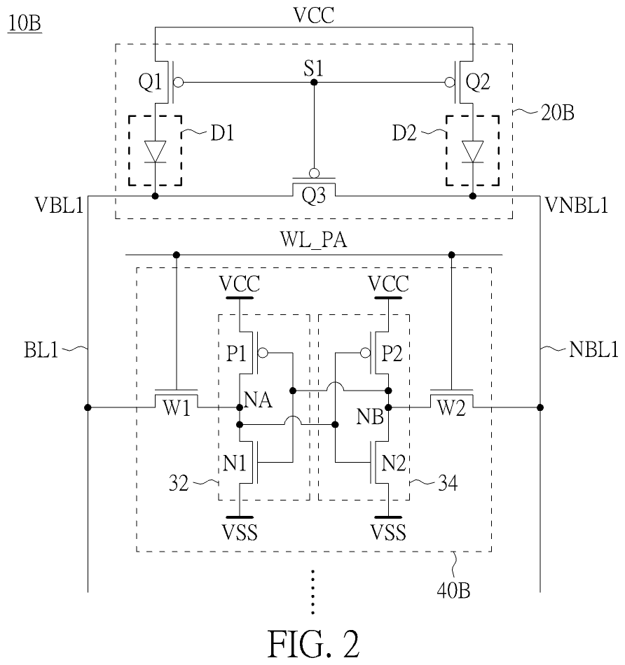

Please refer to FIG. 2, which is a circuit diagram of a static random access memory (SRAM) 10B according to another embodiment of the present invention. The SRAM 10B is a single-port SRAM, which comprises a plurality of SRAM cells 40B and a precharge circuit 20B. Each SRAM cell 40B is coupled to a set of bit lines BL1 and NBL1. The precharge circuit 20B is used to output precharge voltages VBL1 and VNBL1 to the bit lines BL1 and NBL1 based on the precharge signal S1. The precharge circuit 20B comprises transistors Q1, Q2, Q3, an equivalent diode D1, and an equivalent diode D2. The transistors Q1 to Q3 can be P-type transistors. A first end of the transistor Q1 is coupled to the reference voltage source VCC, a second end of the transistor Q1 is coupled to the anode of the equivalent diode D1, and the gate of transistor Q1 being a control end receives the precharge signal S1. A first end of the transistor Q2 is coupled to the reference voltage source VCC, A second end of the transistor Q2 is coupled to the anode of the equivalent diode D2, and the gate of transistor Q2 being a control end receives the precharge signal S1. A first end of the transistor Q3 is coupled to the bit line BL1, a second end of the transistor Q3 is coupled to the bit line NBL1, and the gate of the transistor Q3 being a control end receives the precharge signal S1. The cathode of the equivalent diode D1 is coupled to the bit line BL1, and the cathode of the equivalent diode D2 is coupled to the bit line NBL1. When the precharge signal S1 is at a low voltage, the transistors Q1, Q2, and Q3 are all turned on, causing the bit lines BL1 and NBL1 to be precharged, and making the precharge voltage VBL1 equal to an operating voltage provided by the reference voltage source VCC minus a turn-on voltage of the equivalent diode D1, and the precharge voltage VNBL1 equal to the operating voltage provided by the reference voltage source VCC minus a turn-on voltage of equivalent diode D2. Assuming that the operating voltage provided by the reference voltage source VCC is Vcc, the turn-on voltage of equivalent diode D1 is V_{1ON}, and the turn-on voltage of equivalent diode D2 is V_{2ON}, then the precharge voltages VBL1 and VNBL1 in the embodiment can be represented by the following equations (1) and (2) respectively:

VBL1=Vcc−V_{1ON} (1)

VNBL1=Vcc−V_{2ON} (2)

Where, the operating voltage Vcc is greater than the turn-on voltages V_{1ON} and V_{2ON} and the precharge voltages VBL1 and VNBL1, the operating voltage Vcc can be between 0.88 volts and 1.32 volts, and the turn-on voltages V_{1ON} and V_{2ON} can be between 200 millivolts and 300 millivolts (i.e., 200 mV to 300 mV).

The SRAM cell 40B is a 6T structure SRAM cell, that is, each SRAM cell 40B comprises six transistors, and the six transistors are two switches and four transistors. The two switches are the switches W1 and W2 composed of N-type transistors, and the four transistors are the two N-type transistors N1, N2 and the two P-type transistors P1, P2. The difference between the SRAM cell 40B and the SRAM cell 40A in FIG. 1 is that: compared to the SRAM cell 40A, the SRAM cell 40B lacks the two switches W3 and W4 of the SRAM cell 40A. Since the SRAM cell 40B in the embodiment lacks the switches W3 and W4, the SRAM 10B also does not need the two bit lines BL2 and NBL2 and word line WL_PB coupled to switches W3 and W4 in FIG. 1. Since the above-mentioned read and write operations of SRAM 10A are illustrated using both the port A and the port B, the single-port operations of the SRAM 10B in the “standby”, “read” and “write” states can be derived from the double-port operations of the SRAM 10A. In other words, simply ignore the relevant settings of the port B in the double-port operation of the SRAM 10A, which is the setting of the SRAM 10B when performing the single-port operations.

In addition, because the precharge voltage VBL1 in the embodiment is lower than the operating voltage Vcc by the turn-on voltage V_{1ON}, and the precharge voltage VNBL1 is lower than the operating voltage Vcc by the turn-on voltage V_{2ON}, under the same operating voltage Vcc and the same operating frequency, the power consumption of each SRAM cell 40B will be lower than the power consumption of each SRAM cell 40A. Furthermore, due to the presence of equivalent diodes D1 and D2, the precharge voltages VBL1 and VNBL1 will be slightly lower than the operating voltage Vcc. Therefore, if the operation speed of N-type transistors N1, N2 is faster than the operation speed of P-type transistors P1, P2 (i.e., fast NMOS slow PMOS (FNSP)), when the data stored in SRAM cell 40B changes from “1” to “0” or from “0” to “1”, it can reduce the probability of latch data failure of the two inverters 32 and 34 of the SRAM cell 40B, thereby increasing the stability of the SRAM cell 40B, and improving the static noise margin (SNM) of the SRAM 10B. Regarding the static noise margin, it will be further explained below.

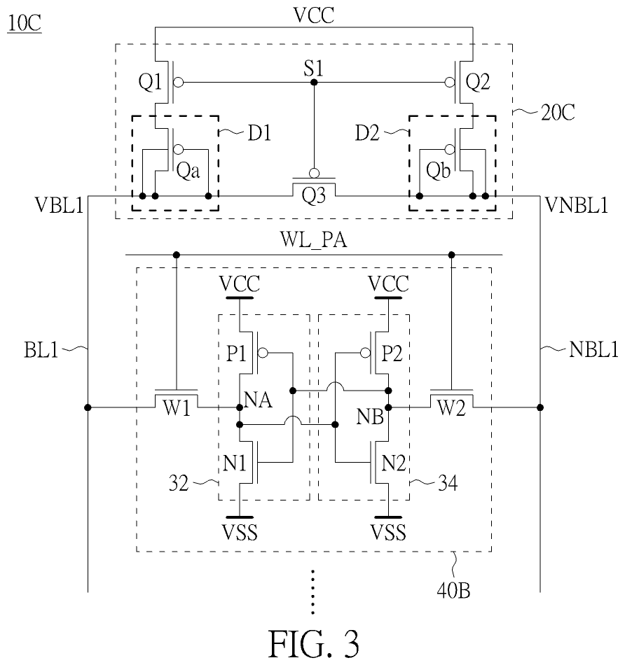

Please refer to FIG. 3, which is a circuit diagram of a static random access memory (SRAM) 10C according to another embodiment of the present invention. The SRAM 10C is a single-port SRAM, which comprises a set of bit lines BL1, NBL1, a precharge circuit 20C, and a plurality of SRAM cells 40B. The precharge circuit 20C is used to output the precharge voltages VBL1 and VNBL1 to the bit lines BL1 and NBL1 based on the precharge signal S1. The precharge circuit 20C comprises transistors Q1, 02, 03, an equivalent diode D1, and an equivalent diode D2. The equivalent diode D1 comprises a buck transistor Qa, and the equivalent diode D2 comprises a buck transistor Qb. The drain, the gate, and the bulk of the buck transistor Qa are coupled to the bit line BL1, and the drain, the gate, and the bulk of the buck transistor Qb are coupled to the bit line NBL1. Assuming that the threshold voltage of the buck transistor Qa is Vₜₕₐ, and the threshold voltage of the buck transistor Qb is V_{thb}, then the precharge voltages VBL1 and VNBL1 in the embodiment can be represented by the following equations (3) and (4) respectively:

VBL1=Vcc−Vₜₕₐ (3)

VNBL1=Vcc−V_{thb} (4)

Where, the threshold voltage Vₜₕₐ can be equal to the turn-on voltage V_{1ON} of the equivalent diode D1, and the threshold voltage V_{thb} can be equal to the turn-on voltage Von of the equivalent diode D2. In addition, the operating voltage Vcc is greater than the threshold voltages Vₜₕₐ and V_{thb} and the precharge voltages VBL1 and VNBL1, the operating voltage Vcc can be between 0.88 volts and 1.32 volts, and the threshold voltages Vₜₕₐ and V_{thb} can be between 200 millivolts and 300 millivolts. The operations of SRAM 10C are the same as those of the SRAM 10B in FIG. 2, and will not be described here again.

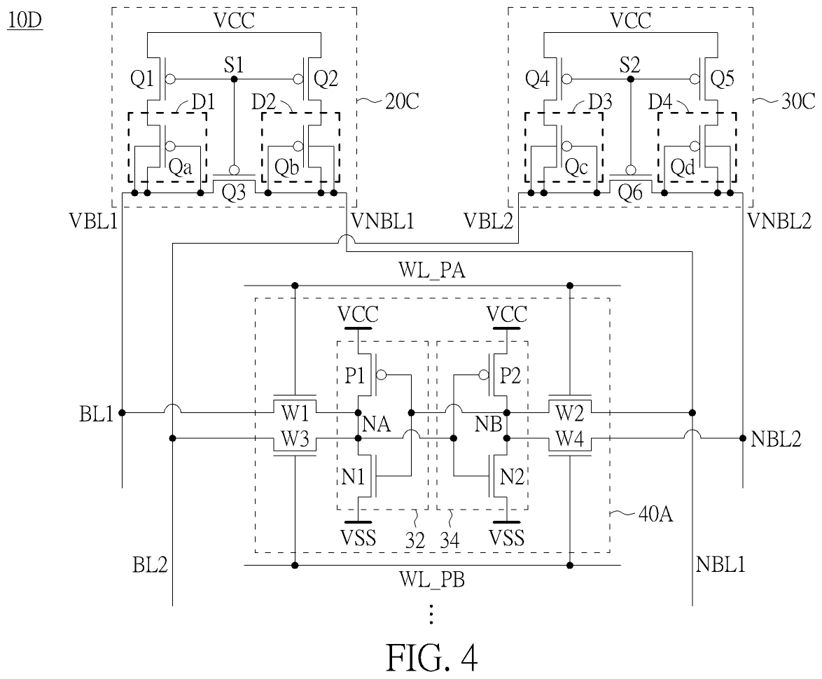

Please refer to FIG. 4, which is a circuit diagram of a static random access memory (SRAM) 10D according to an embodiment of the present invention. The SRAM 10D is a dual-port SRAM, and its difference from the SRAM 10A in FIG. 1 is that: the two precharge circuits 20A and 30A of SRAM 10A are replaced by the two precharge circuits 20C and 30C of SRAM 10D. The precharge circuit 20C in FIG. 4 is the same as the precharge circuit 20C in FIG. 3, and the precharge circuit 30C is used to output the precharge voltages VBL2 and VNBL2 to the bit lines BL2 and NBL2 based on the precharge signal S2. The precharge circuit 30C comprises transistors Q4, 05, 06, an equivalent diode D3, and an equivalent diode D4. The equivalent diode D3 comprises a buck transistor Qc, and the equivalent diode D4 comprises a buck transistor Qd. The drain, the gate, and the bulk of the buck transistor Qc are coupled to the bit line BL2, and the drain, the gate, and the bulk of the buck transistor Qd are coupled to the bit line NBL2. Assuming that the threshold voltage of the buck transistor Qc is Vₜₕₑ, and the threshold voltage of the buck transistor Qd is V_{thd}, then the precharge voltages VBL2 and VNBL2 in the embodiment can be represented by the following equations (5) and (6) respectively:

VBL2=Vcc−Vₜₕₑ (5)

VNBL2=Vcc−V_{thd} (6)

Where, the threshold voltage Vₜₕₑ can be equal to a turn-on voltage of the equivalent diode D3, and the threshold voltage V_{thd} can be equal to a turn-on voltage of the equivalent diode D4. In addition, the operating voltage Vcc is greater than the threshold voltages Vₜₕₑ and V_{thd} and precharge voltages VBL2 and VNBL2, the operating voltage Vcc can be between 0.88 volts and 1.32 volts, and the threshold voltages Vₜₕₑ and V_{thd} can be between 200 millivolts and 300 millivolts. Moreover, because the precharge circuit 20C in FIG. 4 is the same as the precharge circuit 20C in FIG. 3, the precharge voltages VBL1 and VNBL1 in FIG. 4 can also be represented by the above equations (3) and (4). The main difference between the SRAM 10D and the SRAM 10A in FIG. 1 is that the precharge voltages VBL1, VNBL1, VBL2, and VNBL2 will be slightly lower than the operating voltage Vcc due to the equivalent diodes D1, D2, D3, and D4, and the rest is the same and will not be further elaborated here.

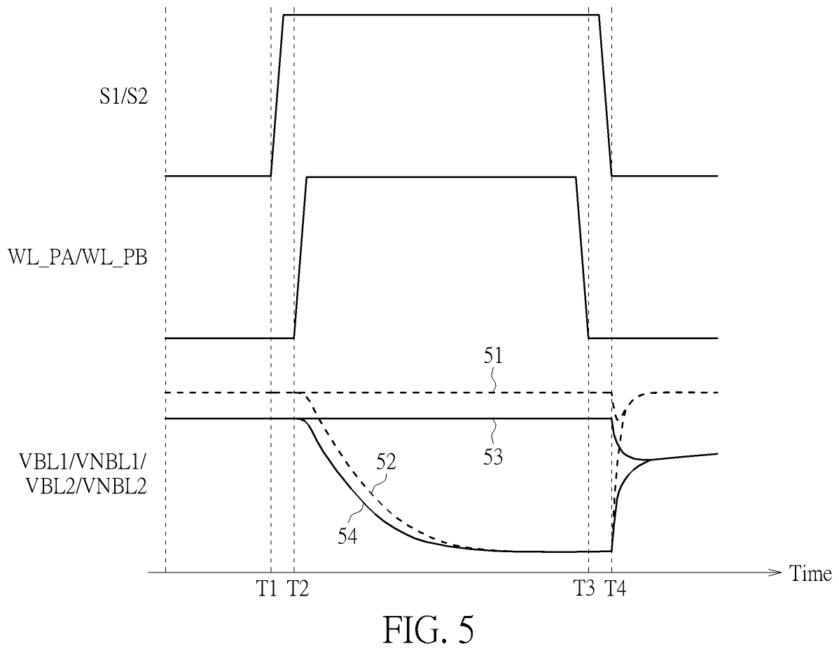

Please refer to FIGS. 1, 4 and 5. FIG. 5 is the timing diagram of the related voltages during the read operations of the SRAMs 10A and 10D in FIGS. 1 and 4. The curves 51 and 52 are used to represent the timing of the precharge voltages VBL1, VNBL1, VBL2, and VNBL2 of the SRAM 10A, while the curves 53 and 54 are used to represent the timing of the precharge voltages VBL1, VNBL1, VBL2, and VNBL2 of the SRAM 10D. The precharge voltage VBL1 is equal to the precharge voltage VBL2, and the precharge voltage VNBL1 is equal to the precharge voltage VNBL2. In detail, if the data stored in the SRAM cell 40A of the SRAM 10A is “1”, the curve 51 represents the timing of the precharge voltages VBL1 and VBL2 of the SRAM 10A, and the curve 52 represents the timing of the precharge voltages VNBL1 and VNBL2 of the SRAM 10A. If the data stored in the SRAM cell 40A of the SRAM 10A is “0”, the curve 51 represents the timing of the precharge voltages VNBL1 and VNBL2 of the SRAM 10A, and the curve 52 represents the timing of the precharge voltages VBL1 and VBL2 of the SRAM 10A. Similarly, if the data stored in the SRAM cell 40A of the SRAM 10D is “1”, the curve 53 represents the timing of the precharge voltages VBL1 and VBL2 of the SRAM 10D, and the curve 54 represents the timing of the precharge voltages VNBL1 and VNBL2 of the SRAM 10D. If the data stored in the SRAM cell 40A of the SRAM 10D is “0”, the curve 53 represents the timing of the precharge voltages VNBL1 and VNBL2 of the SRAM 10D, and the curve 54 represents the timing of the precharge voltages VBL1 and VBL2 of the SRAM 10D. At time point T1, the two precharge signals S1 and S2 start to be pulled up from low level, in preparation to turn off the transistors Q1 to Q6 that have already been turned on, and then prepare to end the precharge operation. At time point T2, the two word lines WL_PA and WL_PB start to be pulled up from low level, in preparation to turn on the switches W1 to W4. At time point T3, the two word lines WL_PA and WL_PB are pulled down to low level, to turn off the switches W1 to W4. At time point T4, the two precharge signals S1 and S2 are pulled down to low level, to turn on the transistors Q1 to Q6. Therefore, the time period before time point T1 and the time period after time point T4 shown in FIG. 5 are both the periods for precharging the bit lines BL1, BL2, NBL1, and NBL2. During the precharge periods, the precharge voltages VBL1, VNBL1, VBL2, and VNBL2 of the SRAM 10A (as indicated by the curves 51 and 52) will be higher than the precharge voltages VBL1, VNBL1, VBL2, and VNBL2 of the SRAM 10D (as indicated by the curves 53 and 54).

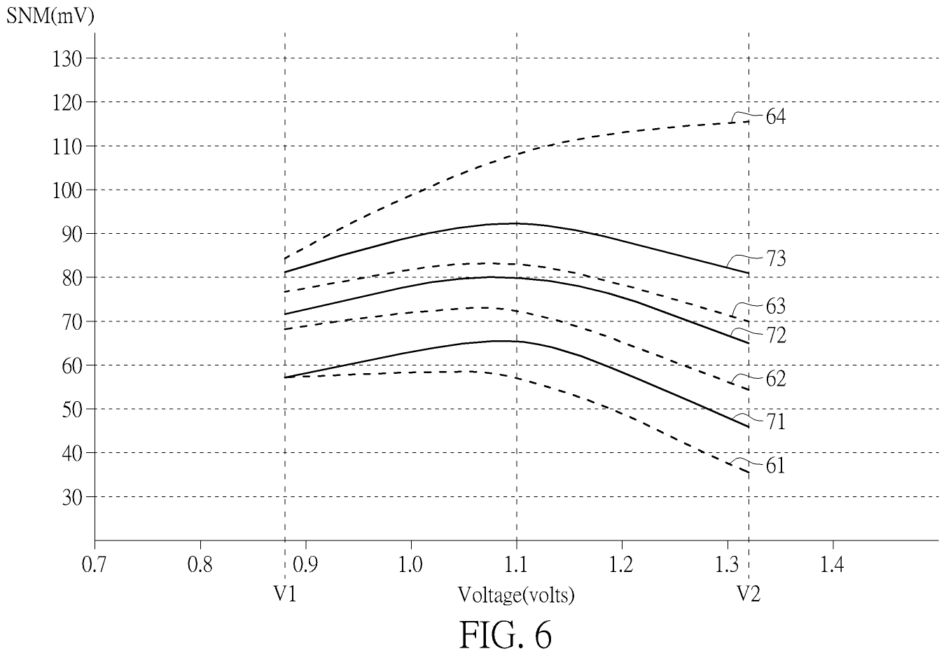

Please refer to FIG. 6. FIG. 6 is a diagram showing relationship between the operating voltage and the static noise margin (SNM) of the SRAM 10A and 10D shown in FIGS. 1 and 4. The horizontal axis represents the operating voltage provided by the reference voltage source VCC, and the vertical axis represents the SNM of SRAM 10A and 10D. Static noise margin (SNM) is an important parameter for measuring the stability and noise immunity of digital logic gates. It is defined as the maximum input noise amplitude that a digital logic gate can tolerate without causing an error in the output. Therefore, the SNM can be used to evaluate the stability of the SRAM cells. The greater the SNM value of an SRAM cell, the stronger its immunity to noise and the better its data retention stability. In the read operation of the SRAM, the read lines and bit lines are affected by noise, and the SNM can be used to measure the degree of noise impact on the output voltage. If the amplitude of the noise exceeds the SNM, it may cause errors in the output voltage, leading to reading errors. In FIG. 6, the curves 61, 62, 63, and 64 represent the SNM of the SRAM 10A in FIG. 1 at 175° C., 150° C., 125° C., and 25° C. respectively, while the curves 71, 72, and 73 represent the SNM of the SRAM 10D in FIGS. 4 at 175° C., 150° C., and 125° C. respectively. According to the curves 61 and 71, at an operating voltage of V1 and a temperature of 175° C., the SNM of the SRAMs 10A and 10D are both 57 millivolts (mV); at an operating voltage of 1.1 volts and a temperature of 175° C., the SNM of the SRAMs 10A and 10D are 57 mV and 65 mV, respectively; at an operating voltage of V2 and a temperature of 175° C., the SNM of the SRAMs 10A and 10D are 36 mV and 47 mV, respectively. V1=1.1 volts*(100%−20%)=0.88 volts, and V2=1.1 volts*(100%+20%)=1.32 volts. According to the curves 62 and 72, at an operating voltage of V1 and a temperature of 150° C., the SNM of the SRAMs 10A and 10D are 69 mV and 72 mV, respectively; at an operating voltage of 1.1 volts and a temperature of 150° C., the SNM of the SRAMs 10A and 10D are 72 mV and 80 mV, respectively; at an operating voltage of V2 and a temperature of 150° C., the SNM of the SRAMs 10A and 10D are 55 mV and 66 mV, respectively. According to curves 63 and 73, at an operating voltage of V1 and a temperature of 125° C., the SNM of the SRAMs 10A and 10D are 77 mV and 82 mV, respectively; at an operating voltage of 1.1 volts and a temperature of 125° C., the SNM of the SRAMs 10A and 10D are 83 mV and 92 mV, respectively; at an operating voltage of V2 and a temperature of 125° C., the SNM the of the SRAMS 10A and 10D are 70 mV and 81 mV, respectively. Therefore, at the same operating voltage and temperature, the SRAM 10D has a greater SNM than the SRAM 10A. Therefore, the SRAM 10D has better noise immunity than the SRAM 10A. Additionally, since the precharge voltages VBL1, VNBL1, VBL2, and VNBL2 of the SRAM 10D are lower than the operating voltage Vcc, the power consumption of each SRAM cell 40A of the SRAM 10D will be lower than the power consumption of each SRAM cell 40A of the SRAM 10A at the same operating voltage Vcc and the same operating frequency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A static random access memory (SRAM), comprising:
a first precharge circuit, comprising:
a first transistor, comprising:
a first end coupled to a first reference voltage source;
a second end; and
a control end configured to receive a first precharge signal;
a second transistor, comprising:
a first end coupled to the first reference voltage source;
a second end; and
a control end configured to receive the first precharge signal;
a first equivalent diode, comprising;
an anode coupled to the second end of the first transistor; and
a cathode configured to output a first precharge voltage;
a second equivalent diode, comprising;
an anode coupled to the second end of the second transistor; and
a cathode configured to output a second precharge voltage; and
a third transistor, comprising:
a first end coupled to the cathode of the first equivalent diode;
a second end coupled to the cathode of the second equivalent diode; and
a control end configured to receive the first precharge signal;
a first bit line coupled to the cathode of the first equivalent diode and configured to receive the first precharge voltage;
a second bit line coupled to the cathode of the second equivalent diode and configured to receive the second precharge voltage; and
a plurality of SRAM cells, each SRAM cell being coupled between the first bit line and the second bit line.

2. The static random access memory of claim 1, wherein the first reference voltage source provides an operating voltage, and the first precharge voltage and the second precharge voltage are both less than the operating voltage.

3. The static random access memory of claim 1, wherein the first equivalent diode further comprises a first buck transistor, and a drain, a gate, and a bulk of the first buck transistor are coupled to the first bit line; and
wherein the second equivalent diode further comprises a second buck transistor, and a drain, a gate, and a bulk of the second buck transistor are coupled to the second bit line.

4. The static random access memory of claim 1, further comprising:
a second precharge circuit, comprising:
a fourth transistor, comprising:
a first end coupled to the first reference voltage source;
a second end; and
a control end configured to receive a second precharge signal;
a fifth transistor, comprising:
a first end coupled to the first reference voltage source;
a second end; and
a control end configured to receive the second precharge signal;
a third equivalent diode, comprising;
an anode coupled to the second end of the fourth transistor; and
a cathode configured to output a third precharge voltage;
a fourth equivalent diode, comprising;
an anode coupled to the second end of the fifth transistor; and
a cathode configured to output a fourth precharge voltage; and
a sixth transistor, comprising:
a first end coupled to the cathode of the third equivalent diode;
a second end coupled to the cathode of the fourth equivalent diode; and
a control end configured to receive the second precharge signal;
a third bit line coupled to the cathode of the third equivalent diode and configured to receive the third precharge voltage; and
a fourth bit line coupled to the cathode of the fourth equivalent diode and configured to receive the fourth precharge voltage.

5. The static random access memory of claim 4, wherein the first reference voltage source is used to provide an operating voltage, and the first precharge voltage, the second precharge voltage, the third precharge voltage, and the fourth precharge voltage are all less than the operating voltage.

6. The static random access memory of claim 4, wherein each SRAM cell is coupled between the third bit line and the fourth bit line.

7. The static random access memory of claim 4, wherein each SRAM cell is an 8T SRAM cell.

8. The static random access memory of claim 4, further comprising:
a first word line; and
a second word line;
wherein each SRAM cell comprises:
a first inverter;
a second inverter, wherein an input end of the second inverter is coupled to an output end of the first inverter, and an output end of the second inverter is coupled to an input end of the first inverter;
a first switch, comprising:
a first end coupled to the first bit line;
a second end coupled to the input end of the first inverter and the output end of the second inverter; and
a control end coupled to the first word line;
a second switch, comprising:
a first end coupled to the second bit line;
a second end coupled to the output end of the first inverter and the input end of the second inverter; and
a control end coupled to the first word line;
a third switch, comprising:
a first end coupled to the third bit line;
a second end coupled to the input end of the first inverter and the output end of the second inverter; and
a control end coupled to the second word line; and
a fourth switch, comprising:
a first end coupled to the fourth bit line;
a second end coupled to the output end of the first inverter and the input end of the second inverter; and
a control end coupled to the second word line.

9. The static random access memory of claim 8, wherein the first inverter comprises:
a first P-type transistor, comprising:
a first end coupled to the first reference voltage source;
a second end coupled to the second end of the first switch and the second end of the third switch; and
a control end coupled to the second end of the second switch and the second end of the fourth switch; and
a first N-type transistor, comprising:
a first end coupled to the second end of the first P-type transistor;
a second end coupled to a second reference voltage source; and
a control end coupled to the control end of the first P-type transistor; and
wherein the second inverter comprises:
a second P-type transistor, comprising:
a first end coupled to the first reference voltage source;
a second end coupled to the control end of the first P-type transistor; and
a control end coupled to the second end of the first switch and the second end of the third switch; and
a second N-type transistor, comprising:
a first end coupled to the control end of the first P-type transistor;
a second end coupled to the second reference voltage source; and
a control end coupled to the second end of the first P-type transistor.

10. The static random access memory of claim 1, further comprising a word line;
wherein each SRAM cell comprises:
a first inverter;
a second inverter, wherein an input end of the second inverter is coupled to an output end of the first inverter, and an output end of the second inverter is coupled to an input end of the first inverter;
a first switch, comprising:
a first end coupled to the first bit line;
a second end coupled to the input end of the first inverter and the output end of the second inverter; and
a control end coupled to the word line; and
a second switch, comprising:
a first end coupled to the second bit line;
a second end coupled to the output end of the first inverter and the input end of the second inverter; and
a control end coupled to the word line.

11. The static random access memory of claim 10, wherein each SRAM cell is a 6T SRAM cell.

12. The static random access memory of claim 10, wherein the first inverter comprises:
a first P-type transistor, comprising:
a first end coupled to the first reference voltage source;
a second end coupled to the second end of the first switch; and
a control end coupled to the second end of the second switch; and
a first N-type transistor, comprising:
a first end coupled to the second end of the first P-type transistor;
a second end coupled to a second reference voltage source; and
a control end coupled to the control end of the first P-type transistor; and
wherein the second inverter comprises:
a second P-type transistor, comprising:
a first end coupled to the first reference voltage source;
a second end coupled to the control end of the first P-type transistor; and
a control end coupled to the second end of the first switch; and
a second N-type transistor, comprising:
a first end coupled to the control end of the first P-type transistor;
a second end coupled to the second reference voltage source; and
a control end coupled to the second end of the first P-type transistor.

13. The static random access memory of claim 12, wherein the first reference voltage source provides an operating voltage, the second reference voltage source provides a ground voltage, and the operating voltage is greater than the ground voltage.

14. The static random access memory of claim 1, wherein the first transistor, the second transistor, and the third transistor are all P-type transistors.
